(19) United States
(12) Patent Application Publication
(10) Pub. No.: US 2023/0155073 A1
(43) Pub. Date: May 18, 2023

(54) LIGHT-EMITTING DIODE (LED) PACKAGE WITH REFLECTIVE COATING AND METHOD OF MANUFACTURE

(71) Applicant: LUMILEDS LLC, San Jose, CA (US)

(72) Inventors: Grigoriy Basin, San Francisco, CA (US); Mikhail Fouksman, Emerald Hill, CA (US); Venkata Ananth Tamma, Boise, ID (US); Tze Yang Hin, Cupertino, CA (US); Kok Siang Saw, Bayan Lepas (MY); Ruen Ching Law, Balik Pulau (MY)

(73) Assignee: LUMILEDS LLC, San Jose, CA (US)

(21) Appl. No.: 17/990,450

(22) Filed: Nov. 18, 2022

Related U.S. Application Data
(60) Provisional application No. 63/280,921, filed on Nov. 18, 2021.

(51) Int. Cl. H01L 33/50; H01L 33/10; H01L 33/34; H01L 33/60

(52) U.S. Cl. CPC H01L 33/50; H01L 33/10; H01L 33/346; H01L 33/60

(57) ABSTRACT

A light-emitting diode (LED) package and method of manufacture are described. An LED package includes an LED die that has a top surface, a bottom surface and side surfaces. The package further includes a wavelength converting element having a top surface, a bottom surface and side surfaces. The bottom surface of the wavelength converting element is adjacent the top surface of the LED die. The package further includes a light reflecting coating surrounding at least the side surfaces of both the LED die and the wavelength converting element. The light reflective coating has at a least a portion that extends above the top surface of the wavelength converting element.

### CROSS REFERENCE TO RELATED APPLICATION(S)

This application claims the benefit of U.S. Provisional Application No. 63/280,921, filed Nov. 18, 2021, which is incorporated by reference as if fully set forth.

### BACKGROUND

Achieving high beam intensity performance is becoming increasingly important for automotive front lighting applications, for example. Automotive front lighting hot spot intensity may depend, for example, on LED luminance, system optics and LED package design. Automotive LEDs often use chip scale package (CSP) dies because they may be both highly reliable and highly efficient.

### SUMMARY

A light-emitting diode (LED) package and method of manufacture are described. An LED package includes an LED die that has a top surface, a bottom surface and side surfaces. The package further includes a wavelength converting element having a top surface, a bottom surface and side surfaces. The bottom surface of the wavelength converting element is adjacent the top surface of the LED die. The package further includes a light reflecting coating surrounding at least the side surfaces of both the LED die and the wavelength converting element. The light reflective coating has at a least a portion that extends above the top surface of the wavelength converting element.

### BRIEF DESCRIPTION OF THE DRAWINGS

A more detailed understanding can be had from the following description, given by way of example in conjunction with the accompanying drawings wherein:

FIG. 1 is a cross-sectional view of a CSP LED package having a typical geometry achieved after either direct dispense or molding and bead blasting processes;

FIG. 2A is a cross-sectional view of an example CSP LED package;

FIG. 2B is a cross-sectional view of another example CSP LED package;

FIGS. 3A, 3B, 3C and 3D are cross-sectional views showing various manufacturing stages in an example method of manufacturing an LED package;

FIG. 4 is a flow diagram of the example method of manufacturing the LED package;

FIGS. 5A and 5B are cross-sectional views showing various manufacturing stages in an example method of manufacturing LED die assemblies;

FIG. 6 is a flow diagram of the example method of manufacturing LED die assemblies;

FIG. 7 is a diagram of an example vehicle headlamp system; and

FIG. 8 is a diagram of another example vehicle headlamp system.

### DETAILED DESCRIPTION

Examples of different light illumination systems and/or light emitting diode (“LED”) implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

It will be understood that, although the terms first, second, third, etc. may be used herein to describe various elements, these elements should not be limited by these terms. These terms may be used to distinguish one element from another. For example, a first element may be termed a second element and a second element may be termed a first element without departing from the scope of the present invention. As used herein, the term “and/or” may include any and all combinations of one or more of the associated listed items.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there may be no intervening elements present. It will also be understood that when an element is referred to as being “connected” or “coupled” to another element, it may be directly connected or coupled to the other element and/or connected or coupled to the other element via one or more intervening elements. In contrast, when an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

When CSP dies are used in automotive applications, for example, it may be important to surround the LED die and wavelength converting element with a high reflectivity material. This will ensure, for example, that the LED has the highest possible brightness while minimizing stray light. This may be done, for example, using a molding or direct dispense process to coat side walls of the LED die and wavelength converting element with a high light reflectivity material. The high light reflectivity material may serve as a light reflector, minimizing stray light, improving package efficiency, and providing sharp luminance cut-off outside of the light emitting area (LEA) of the die. The side coat molding process is often followed by bead-blasting, which may be necessary to remove excess side coating material from the top surface of the wavelength converting element.

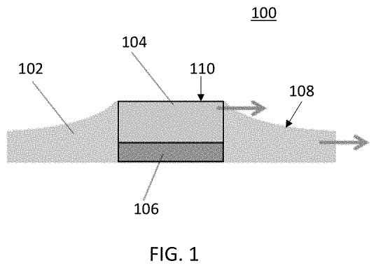

FIG. 1 is a cross-sectional view of a CSP LED package 100 having a typical geometry achieved after either direct dispense or molding and bead blasting processes. In the example illustrated in FIG. 1, the CSP LED package 100 includes an LED die 106, a wavelength converting material 104 over the LED die 106 and a reflective side coating 102 surrounding side surfaces of the LED die 106 and the wavelength converting material 104. In the example illustrated in FIG. 1, the reflective side coating 102 has a curved meniscus on the top surface 108, which may result from surface tension during dispensing.

The arrows in FIG. 1 illustrate a potential issue with the curved meniscus shaped top surface 108. For example, the thickness of the reflective side coating 102 from outer edges of the LED die 106 and the wavelength converting material 104 towards the outer edges of the CSP LED package 100 is non-uniform, which may permit light to leak out through side surfaces of the CSP LED package 100. For example, some areas will have a much thinner reflective side coating 102 than other areas, and the areas under a certain thickness may permit light to leak through without reflecting back into the LED die 106 or the wavelength converting material 104 for color conversion and eventual emission through the top surface 110 of the wavelength converting material 104. For another example, some of the reflective side coating 102 may be removed from areas where removal is not desired during the bead blasting process, which may also result in light leakage through side surfaces of the CSP LED package 100. Such light leakage may be significantly disadvantageous for applications where high etendue of light is required.

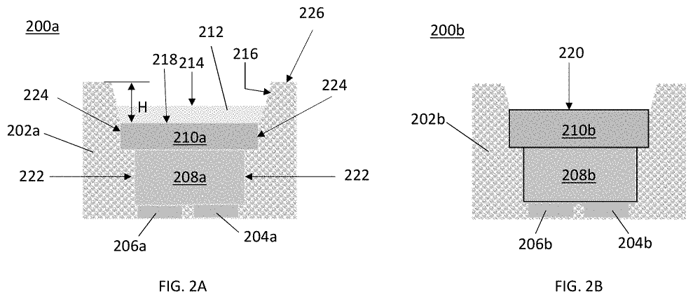

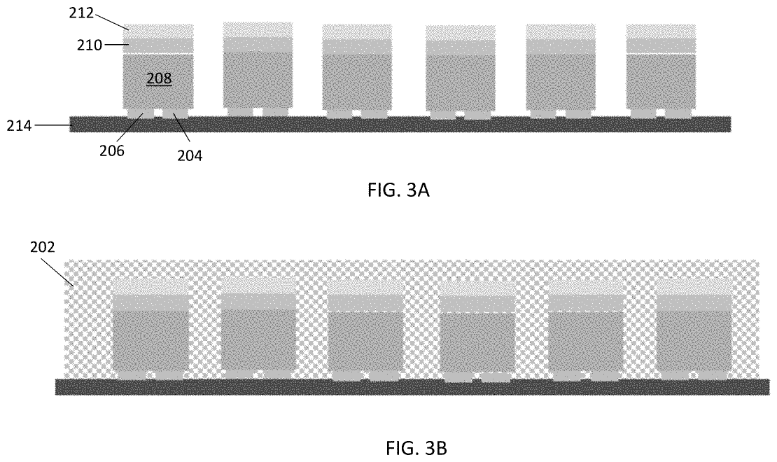

FIG. 2A is a cross-sectional view of an example CSP LED package 200a. In the example illustrated in FIG. 2A, the CSP LED package 200a includes an LED die 208a, a wavelength converting material 210a, electrical contacts 204a and 206a, a reflective side coating 202a and a sacrificial material 212. The LED die 208a may be any type of LED die. In some embodiments, the LED die 208a may be an InGaN flip chip pattern surface sapphire die. However, many other LED dies may be used without departing from the embodiments described herein. The LED die 208a may include a stack of semiconductor layers, which may include one or more n-type layers doped with, for example, Si, formed over a substrate, one or more light emitting layers in an active region formed over the n-type layer or layers, and one or more p-type layers doped with, for example, Mg, formed over the active region. Electrical contacts 204a and 206a may be formed on, adjacent and/or in contact with the n- and p-type regions, respectively.

In some embodiments, the wavelength converting material 210a may be or include phosphors, such as conventional phosphors, powder phosphors or organic phosphors and may be in the form of a pre-formed structure or particles dispersed in a binder matrix, for example. In some embodiments, the wavelength converting material 210a may be a ceramic phosphor layer. The wavelength converting material 210a may be disposed over the LED die 208a and may have a bottom surface (not labeled) in direct contact with a top surface (not labeled) of the LED die 208a or may be secured to the top surface of the LED die 208a by an adhesive material.

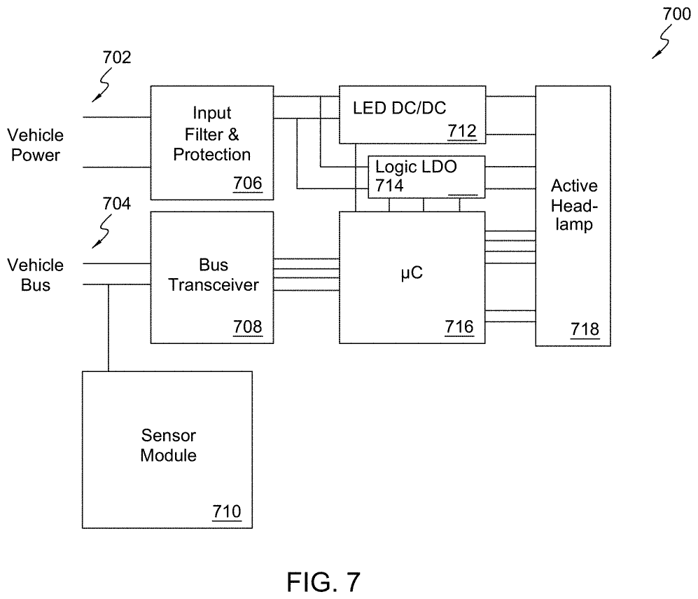

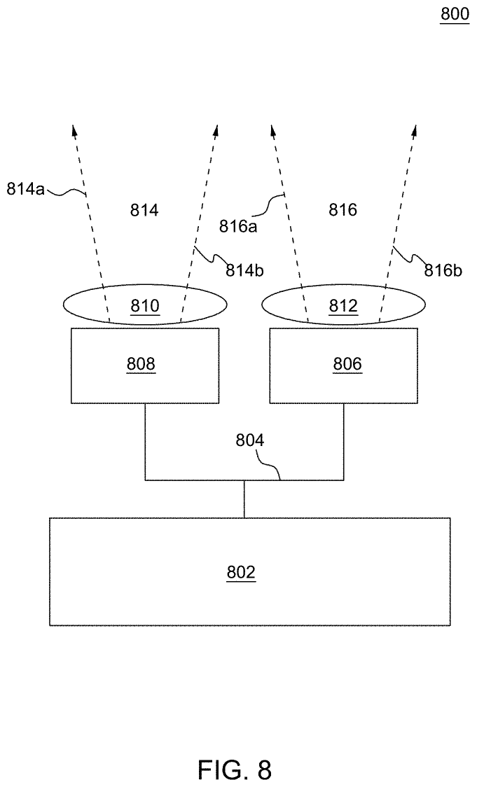

A reflective side coating 202a may be disposed surrounding side surfaces 222 of the LED die 208a and side surfaces 224 of the wavelength converting material 210a. By comparison to the CSP LED package 100 illustrated in FIG. 1, the reflective side coating 202a extends above a top surface 218 of the wavelength converting material 210a. Further, an inner surface 216 of the portion of the reflective side coating 202a that extends above the top surface 218 of the wavelength converting material 210a may be slanted or tapered such that a width of the reflective side coating 202a may decrease from at least or around the top surface 218 of the wavelength converting material 210a to a top surface 226 of the reflective side coating 202a. This design may increase optical system efficiency and hot spot intensity and may be beneficial for applications, such as flash modules, automotive front lighting or projection LED systems. In some embodiments, the reflective side coating 202a may extend a distance H above the top surface 218 of the wavelength converting material 210a. The distance H may be, for example, 30-100 μm, which may eliminate side light emission through side surfaces of the CSP LED package 200a and help to direct the light through the light emission surface 214 and towards the optics (examples are shown in FIGS. 7 and 8 below) with minimal light losses. The reflective side coating 202a may be a highly light reflective side coating, such 90% reflective or greater. The reflectivity of the coating may depend, for example, on the thickness of the coating and, therefore, the reflective side coating 202a may have a uniform or substantially uniform thickness such that 90% or greater reflectivity may be achieved.

In the example illustrated in FIG. 2A, a sacrificial material 212 is provided over the wavelength converting material 210a. In some embodiments, the sacrificial material 212 may be placed over the wavelength converting material 210a as part of the manufacturing process, and all or a portion may be left on to ensure that portions of the wavelength converting material 210a or reflective side coating 202a are not undesirably removed as a bi-product. Additionally, or alternatively, at least a portion of the sacrificial material 214 may be left on intentionally to protect the wavelength converting material 210a from damage and/or contaminants. The sacrificial material 212 may be, for example, a silicone or silicone filled with inorganic material with matching refraction index.

FIG. 2B is a cross-sectional view of another example CSP LED package 200b. The example CSP LED package 200b is similar to the CSP LED package 200a of FIG. 2A except that the sacrificial material 212 has been completely or substantially removed such that a negligible amount remains or is otherwise not included. Since the sacrificial material 212 is not present or not visible in FIG. 2B, the light-emitting surface may be or may essentially be the top surface 220 of the wavelength converting material 210b. Unless otherwise stated, the LED die 208b, the wavelength converting material 210b, the electrical contacts 204b and 206b and the reflective side coating 202b may be the same as or similar to the corresponding components in FIG. 2A.

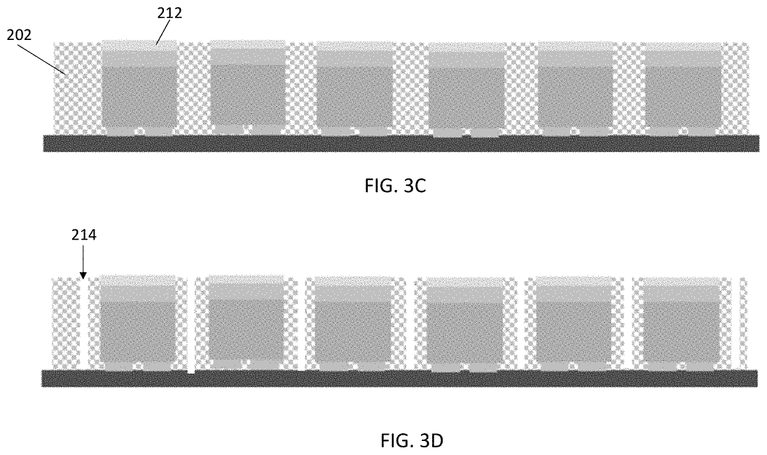

While in FIGS. 2A and 2B, the various elements have different widths (e.g., the wavelength converting layer is wider than the LED die and the sacrificial layer is wider than the wavelength converting layer), the elements can also be the same, smaller or substantially the same width, as shown in FIGS. 3A, 3B, 3C and 3D, consistent with the embodiments described herein.

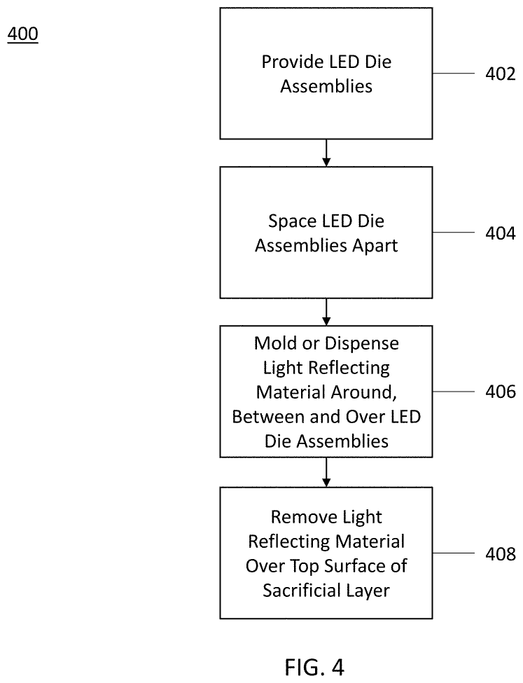

FIGS. 3A, 3B, 3C and 3D are cross-sectional views showing various manufacturing stages in an example method of manufacturing an LED package. FIG. 4 is a flow diagram 400 of the example method of manufacturing the LED package.

In the example illustrated in FIG. 4, the method includes providing LED die assemblies (402). The method may also include spacing the LED die assemblies apart (404). FIG. 3A shows and example of multiple LED dies spaced apart. In the example illustrated in FIG. 3A, the multiple LED dies are spaced apart on a temporary substrate 214, such as a tape or other substrate that may be easily removed once the LED packages are complete and/or singulated into individual LED packages. In the example illustrated in FIG. 3A, each of the LED die assemblies may include an LED die 208, a wavelength converting element 210 and a sacrificial layer 212. The wavelength converting element 210 may have a bottom surface adjacent a top surface of the LED die. The LED die may include electrodes 204 and 206, which may be disposed on, over or otherwise in contact with the temporary substrate 214. The sacrificial layer 212 may have a bottom surface adjacent a top surface of the wavelength converting element.

The example method of manufacturing the LED package may include molding or dispensing a light reflecting material around, between and over the LED die assemblies (406). FIG. 3B shows an example of the multiple LED dies spaced apart with the light reflecting material 202 molded around them. In some embodiments, as mentioned above, the light reflecting material may be or include liquid silicone or a silicone molding compound that may include light reflecting particles and/or material/pigment. The light reflecting material may completely cover the side surfaces of the LED die assemblies and/or the areas between the LED die assemblies and/or the areas between the electrodes. The light reflective material 202 should extend above the top surface of the LED dies (e.g., the top surface of the sacrificial material 212 shown in FIGS. 3A and 3B) so that, when at least the portions of the light reflective material 202 directly above the LED die assemblies is removed, a portion of the light reflective material 202 remains that extends above the LED die assemblies to form packaged LED, such as illustrated in FIGS. 2A and 2B.

The example method of manufacturing the LED package may include removing the light reflective material over the top surface of the sacrificial layer (408). FIG. 3C shows the entire layer of light reflecting material 202 that is above the top surface of the sacrificial material 212 removed with all or some of the sacrificial material 212 still in place. In some embodiments, the light reflecting material 202 may be removed by planarizing or grinding the top layer of the light reflecting material. While all or some of the sacrificial material 212 remains in place in FIG. 3C, as shown in FIG. 2A and described above, all or substantially all of the sacrificial material 212 may be removed consistent with the embodiments described herein. Further, while FIC. 3C shows the top surface of the light reflecting material 202 being co-planar with the top surface of the sacrificial material 212 after removal of the top layer of the light reflecting material 202, in cases where some of the sacrificial material 212 is removed, such as shown in FIG. 2B, for example, it is possible for the top surfaces of the sacrificial material 212 and the light reflecting material 202 to be non-planar consistent with the embodiments described herein.

Although not illustrated in the flow diagram of FIG. 4, the manufacturing stage shown in FIG. 3C may be diced and individual LED packages singulated. FIG. 3D shows an example singulation where cuts or other openings 214 are formed between adjacent LED packages. At this point, the temporary substrate 214 may also be removed to release the individual, singulated LED packages. As shown in FIG. 3D, for example, a portion of the light reflecting material 202 extends above the top surface of the wavelength converting material 210, which enables the individual, singulated LED packages to achieve the benefits described above. As mentioned above, the portions of the light reflecting material that extend above the top surface of the wavelength converting material 210 may be tapered, although not shown in FIG. 3D, to provide additional or alternative benefits, as described above. This may be performed in a number of different ways, such as by forming the sacrificial material 212 to have the desired shape such that the molded light reflecting material 202 takes the desired shape of the sacrificial material or by removing some of the light reflecting material and possibly also some or all of the sacrificial material after molding.

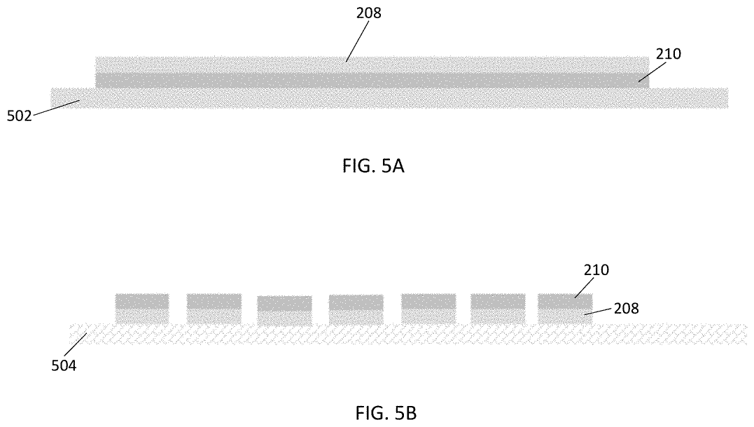

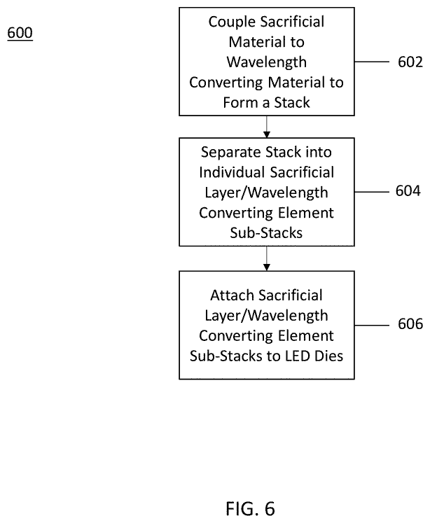

FIGS. 5A and 5B are cross-sectional views showing various manufacturing stages in an example method of manufacturing LED die assemblies. FIG. 6 is a flow diagram 600 of the example method of manufacturing LED die assemblies.

In the example illustrated in FIG. 6, the method includes coupling a sacrificial material to a wavelength converting material to form a stack (602). FIG. 5A shows an example stack including the sacrificial material 208 and the wavelength converting material 210. In some embodiments, the coupling may include or be laminating the sacrificial material to the wavelength converting material and curing the sacrificial material and the wavelength converting material. In some embodiments, the sacrificial material may be or include clear silicone film. In the example illustrated in FIG. 5A, the laminating and curing are performed on a temporary substrate 502, such as a tape.

The example method of manufacturing the LED die assemblies may also include separating the stack into individual sacrificial layer/wavelength converting element sub-stacks (604). The sub-stacks are shown in FIG. 5B. In the example illustrated in FIG. 5B, the stack may be placed on a dicing surface 504, such as a saw tape, prior to the separating. The separating may be done by any dicing or separation method, such as sawing.

The example method of manufacturing the LED die assemblies may also include attaching the sub-stacks to LED dies (606). The fully assembled LED die assemblies are shown, for example, in FIG. 3A. In some embodiments, the sub-stacks may be attached to the LED dies using a glue or other type of adhesive.

FIG. 7 is a diagram of an example vehicle headlamp system 700 that may incorporate one or more of the embodiments and examples described herein. The example vehicle headlamp system 700 illustrated in FIG. 7 includes power lines 702, a data bus 704, an input filter and protection module 706, a bus transceiver 708, a sensor module 710, an LED direct current to direct current (DC/DC) module 712, a logic low-dropout (LDO) module 714, a micro-controller 716 and an active head lamp 718.

The power lines 702 may have inputs that receive power from a vehicle, and the data bus 704 may have inputs/outputs over which data may be exchanged between the vehicle and the vehicle headlamp system 700. For example, the vehicle headlamp system 700 may receive instructions from other locations in the vehicle, such as instructions to turn on turn signaling or turn on headlamps, and may send feedback to other locations in the vehicle if desired. The sensor module 710 may be communicatively coupled to the data bus 704 and may provide additional data to the vehicle headlamp system 700 or other locations in the vehicle related to, for example, environmental conditions (e.g., time of day, rain, fog, or ambient light levels), vehicle state (e.g., parked, in-motion, speed of motion, or direction of motion), and presence/position of other objects (e.g., vehicles or pedestrians). A headlamp controller that is separate from any vehicle controller communicatively coupled to the vehicle data bus may also be included in the vehicle headlamp system 700. In FIG. 7, the headlamp controller may be a micro-controller, such as micro-controller (pc) 716. The micro-controller 716 may be communicatively coupled to the data bus 704.

The input filter and protection module 706 may be electrically coupled to the power lines 702 and may, for example, support various filters to reduce conducted emissions and provide power immunity. Additionally, the input filter and protection module 706 may provide electrostatic discharge (ESD) protection, load-dump protection, alternator field decay protection, and/or reverse polarity protection.

The LED DC/DC module 712 may be coupled between the input filter and protection module 106 and the active headlamp 718 to receive filtered power and provide a drive current to power LEDs in the LED array in the active headlamp 718. The LED DC/DC module 712 may have an input voltage between 7 and 18 volts with a nominal voltage of approximately 13.2 volts and an output voltage that may be slightly higher (e.g., 0.3 volts) than a maximum voltage for the LED array (e.g., as determined by factor or local calibration and operating condition adjustments due to load, temperature or other factors).

The logic LDO module 714 may be coupled to the input filter and protection module 706 to receive the filtered power. The logic LDO module 714 may also be coupled to the micro-controller 716 and the active headlamp 718 to provide power to the micro-controller 716 and/or electronics in the active headlamp 718, such as CMOS logic.

The bus transceiver 708 may have, for example, a universal asynchronous receiver transmitter (UART) or serial peripheral interface (SPI) interface and may be coupled to the micro-controller 716. The micro-controller 716 may translate vehicle input based on, or including, data from the sensor module 710. The translated vehicle input may include a video signal that is transferrable to an image buffer in the active headlamp 718. In addition, the micro-controller 716 may load default image frames and test for open/short pixels during startup. In embodiments, an SPI interface may load an image buffer in CMOS. Image frames may be full frame, differential or partial frames. Other features of micro-controller 716 may include control interface monitoring of CMOS status, including die temperature, as well as logic LDO output. In embodiments, LED DC/DC output may be dynamically controlled to minimize headroom. In addition to providing image frame data, other headlamp functions, such as complementary use in conjunction with side marker or turn signal lights, and/or activation of daytime running lights, may also be controlled.

FIG. 8 is a diagram of another example vehicle headlamp system 800. The example vehicle headlamp system 800 illustrated in FIG. 8 includes an application platform 802, two LED lighting systems 806 and 808, and secondary optics 810 and 812.

The LED lighting system 808 may emit light beams 814 (shown between arrows 814a and 814b in FIG. 8). The LED lighting system 806 may emit light beams 816 (shown between arrows 816a and 816b in FIG. 8). In the embodiment shown in FIG. 8, a secondary optic 810 is adjacent the LED lighting system 808, and the light emitted from the LED lighting system 808 passes through the secondary optic 810. Similarly, a secondary optic 812 is adjacent the LED lighting system 806, and the light emitted from the LED lighting system 806 passes through the secondary optic 812. In alternative embodiments, no secondary optics 810/812 are provided in the vehicle headlamp system.

Where included, the secondary optics 810/812 may be or include one or more light guides. The one or more light guides may be edge lit or may have an interior opening that defines an interior edge of the light guide. LED lighting systems 808 and 806 may be inserted in the interior openings of the one or more light guides such that they inject light into the interior edge (interior opening light guide) or exterior edge (edge lit light guide) of the one or more light guides. In embodiments, the one or more light guides may shape the light emitted by the LED lighting systems 808 and 806 in a desired manner, such as, for example, with a gradient, a chamfered distribution, a narrow distribution, a wide distribution, or an angular distribution.

The application platform 802 may provide power and/or data to the LED lighting systems 806 and/or 808 via lines 804, which may include one or more or a portion of the power lines 702 and the data bus 704 of FIG. 7. One or more sensors (which may be the sensors in the vehicle headlamp system 800 or other additional sensors) may be internal or external to the housing of the application platform 802. Alternatively, or in addition, as shown in the example vehicle headlamp system 700 of FIG. 7, each LED lighting system 808 and 806 may include its own sensor module, connectivity and control module, power module, and/or LED array.

In embodiments, the vehicle headlamp system 800 may represent an automobile with steerable light beams where LEDs may be selectively activated to provide steerable light. For example, an array of LEDs or emitters may be used to define or project a shape or pattern or illuminate only selected sections of a roadway. In an example embodiment, infrared cameras or detector pixels within LED lighting systems 806 and 808 may be sensors (e.g., similar to sensors in the sensor module 710 of FIG. 7) that identify portions of a scene (e.g., roadway or pedestrian crossing) that require illumination.

Having described the embodiments in detail, those skilled in the art will appreciate that, given the present description, modifications may be made to the embodiments described herein without departing from the spirit of the inventive concept. Therefore, it is not intended that the scope of the invention be limited to the specific embodiments illustrated and described.

What is claimed is:

1. A light-emitting diode (LED) package comprising:
an LED die comprising a top surface, a bottom surface and side surfaces;
a wavelength converting element comprising a top surface, a bottom surface and side surfaces, the bottom surface of the wavelength converting element adjacent the top surface of the LED die; and
a light reflecting coating surrounding at least the side surfaces of both the LED die and the wavelength converting element, the light reflective coating comprising at a least a portion that extends above the top surface of the wavelength converting element.

2. The LED package of claim 1, wherein the at least the portion of the light reflective coating that extends above the top surface of the wavelength converting element extends above the top surface by 30-100 μm.

3. The LED package of claim 1, wherein the light reflective coating has a substantially uniform thickness extending from the side surfaces of the wavelength converting element and the side surfaces of the LED die towards an outer side surface of the LED package.

4. The LED package of claim 3, wherein the substantially uniform thickness is such that a reflectivity of the light reflective coating is 90% or greater.

5. The LED package of claim 1, wherein an inner surface of the light reflective coating is tapered at least from the top surface of the wavelength converting element to a top surface of the light reflective coating.

6. The LED package of claim 1, further comprising a sacrificial layer over the wavelength converting element, the sacrificial layer comprising silicone.

7. The LED package of claim 1, wherein the wavelength converting element comprises a ceramic phosphor material or a silicone material comprising phosphor particles.

8. The LED package of claim 1, wherein the LED package is a chip scale package (CSP).

9. The LED package of claim 1, wherein the LED die comprises a plurality of electrodes, and the light reflecting coating fills a space between the plurality of electrodes.

10. The LED package of claim 1, wherein the light reflective material comprises at least one of a liquid silicone or a silicone molding compounded comprising reflective particles or pigment.

11. A method of manufacturing an LED package, the method comprising:
providing a plurality of LED die assemblies, each of the plurality of LED die assemblies comprising an LED die, a wavelength converting element having a bottom surface adjacent a top surface of the LED die, and a sacrificial layer having a bottom surface adjacent a top surface of the wavelength converting element;
spacing the plurality of LED die assemblies apart;
molding a light reflecting material around, between and over the plurality of LED die assemblies; and
removing at least a portion of the light reflecting material over a top surface of the sacrificial layer to form a wafer, such that at least a portion of the light reflecting material remains after the removing and extends above a top surface of the wavelength converting element.

12. The method of claim 11, further comprising removing at least a portion of the sacrificial layer.

13. The method of claim 11, wherein the removing the at least the portion of the light reflecting material over the top surface of the sacrificial layer comprises planarizing or grinding a top layer of the light reflecting material.

14. The method of claim 11, further comprising assembling the plurality of LED die assemblies.

15. The method of claim 14, wherein the assembling the plurality of LED die assemblies comprises:
coupling a sacrificial material to a top surface of a wavelength converting material to form a stack,
separating the stack into a plurality of individual sub-stacks, each of the plurality of individual sub-stacks comprising a portion of the sacrificial layer and a portion of the wavelength converting element, and
coupling one of the sub-stacks to each LED die.

16. The method of claim 15, wherein the coupling the sacrificial layer to the top surface of the wavelength converting element comprises:
laminating a silicone sacrificial material to the top surface of the wavelength converting material, and
curing the silicone sacrificial material and the wavelength converting material.

17. The method of claim 15, wherein the separating the stack into the plurality of individual sub-stacks comprises sawing.

18. The method of claim 15, wherein the coupling one of the sub-stacks to each LED die comprises attaching the sub-stacks to each LED die using a glue adhesive.

19. The method of claim 11, further comprising separating the wafer into a plurality of LED packages.

20. The method of claim 11, further comprising forming the portion of the light reflecting material that remains after the removing into a tapered shape.
